(19) United States
(12) Patent Application Publication
(10) Pub. No.: US 2026/0082860 A1
(43) Pub. Date: Mar. 19, 2026

(54) DEVICES AND METHODS FOR WAFER CENTER FINDING

(71) Applicant: ASM IP Holding B.V., Almere (NL)

(72) Inventors: Theodorus G.M. Oosterlaken, Oudewater (NL); Saeid Bandar Rigi, Amsterdam (NL); Nimit Kothari, Almere (NL)

(21) Appl. No.: 19/328,386

(22) Filed: Sep. 15, 2025

Related U.S. Application Data
(60) Provisional application No. 63/695,168, filed on Sep. 16, 2024.

(51) Int. Cl. H01L 21/68; H01L 21/677

(52) U.S. Cl. CPC H10P 72/53; H10P 72/3302

(57) ABSTRACT

The present disclosure generally relates to the field of semiconductor processing, and in particular devices and methods for handling and accurately positioning wafers during various stages of semiconductor manufacturing. The present disclosure further relates to semiconductor processing systems comprising said specifically designed devices.

### CROSS-REFERENCE TO RELATED APPLICATION(S)

This Application claims the benefit of U.S. Provisional Application 63/695,168 filed on Sep. 16, 2024, the entire contents of which are incorporated herein by reference.

### FIELD OF INVENTION

The present disclosure generally relates to the field of semiconductor processing, and in particular devices and methods for handling and accurately positioning wafers during various stages of semiconductor manufacturing.

### BACKGROUND OF THE DISCLOSURE

In semiconductor manufacturing, wafers and other substrates are typically transferred from one location to another inside a processing system using robotic handlers. However, misalignment or improper handling can lead to defects, reduced throughput, and increased costs. Methods and devices for handling and positioning of wafers are therefore critical for ensuring high yields and device performance during semiconductor processing. Despite significant advancements, current wafer positioning methods face challenges such as alignment precision limits, particularly as wafer sizes increase and feature sizes decrease. In addition, with the advent of optically transparent wafers, existing optical methods for positioning wafers have steadily become more unreliable.

In view of the above, there remains a need for simple and reliable devices and methods for properly positioning wafers and other substrates during robotic transfer from one location to another.

### SUMMARY OF THE DISCLOSURE

It has now been found herein that some or all of the above challenges can be addressed and objectives can be achieved, either individually or in any combination, by using the devices and methods as described herein.

The present summary provides an introduction to a selection of concepts in a simplified form. These concepts are described in further detail in the detailed description of exemplary embodiments of the disclosure below. This summary is not intended to identify key features or essential features of the claimed subject matter, nor is it intended to be used to limit the scope of the claimed subject matter.

In general, the technology disclosed herein relates to the field of semiconductor processing, and in particular improved devices and methods for handling and accurately positioning wafers during semiconductor manufacturing. More specifically, the present disclosure is at least in part based on the finding that traditional optical sensors used to determine the position of the wafer described in the art can be affected by electrical noise, signal distortion, saturation, and interference issues, which may lead to a decreased signal reliability. Moreover, the increasing demand for optically transparent wafers has made accurate detection and positioning even more challenging.

Surprisingly, it has been found herein that a specific device configured to detect the positional coordinates of a wafer or other substrate with light in the UV range (i.e., around 10-400 nm) can circumvent these aforementioned issues. This advantageously allows to determine wafer coordinates, such as the wafer center, with increased sensitivity. Moreover, the present device has the further advantage that it can be conveniently integrated in existing semiconductor manufacturing systems, thus making it a cost-effective solution to current needs. Another advantage of the present device is that it allows to determine wafer coordinates with greater precision, regardless of whether the wafer is composed of an optically transparent material or not.

In accordance with an aspect of the present disclosure, a device is provided for determining the center of a wafer in a semiconductor processing system. The device preferably comprises a plurality of light sources, each light source being independently operable to emit UV light, encompassing radiation having a wavelength from at least 10 nm to at most 400 nm; a plurality of detectors, each detector being independently operable to receive said UV light and produce an electrical signal; and a processor operatively connected to said plurality of detectors and configured to process the produced electrical signal for determining the center of said wafer.

It has been found herein that the present device provides an improved localization efficiency of the positional coordinates, such as the wafer center and/or wafer radius, of various wafers and other substrates during semiconductor processing. This has the advantage that the present disclosure is not bound to a specific material, but can be conveniently applied to various wafers and other suitable substrates as defined herein.

Another advantage of the present device is that the plurality of light sources and detectors are configured to operate in a corresponding (narrow) wavelength range, which leads to more accurate and reliable measurements.

In particular embodiments, each light source of the present device is independently operable to emit UV-A light, encompassing radiation having a wavelength from at least 315 nm to at most 400 nm, and each detector is independently operable to receive said UV-A light and produce an electrical signal.

In particular embodiments, each light source of the present device is independently operable to emit UV-A light at a peak wavelength of around 365 nm; and preferably each detector is independently operable to receive UV-A light at a peak wavelength of around 365 nm.

In particular embodiments, said plurality of light sources are light-emitting diodes.

In particular embodiments, said plurality of detectors are photodiodes.

In particular embodiments, said wafer comprises comprises one or more material selected from the group consisting of silicon carbide, silicon, silicon germanium, silicon oxide, gallium arsenide, gallium nitride, sapphire, and combinations thereof; preferably said wafer comprises silicon carbide as a bulk semiconductor material.

Another aspect of the present disclosure provides a method for finding the center of a wafer in a semiconductor processing system. The method preferably comprising the steps of
providing a wafer to a device according to an aspect of the present disclosure or (preferred) embodiments thereof;
illuminating the outer circumference of said wafer with UV light, encompassing radiation having a wavelength from at least 10 nm to at most 400 nm, emitted by said plurality of light sources and detecting the UV light from said plurality of light sources and/or secondary emissions from said wafer with said plurality of detectors, thereby producing an electrical signal;
converting the electrical signal in said processor, thereby determining the center of said wafer.

Another aspect of the present disclosure provides a method for accurately positioning a wafer in a semiconductor processing system. The method preferably comprising the steps of
providing a wafer to a device, according to an aspect of the present disclosure or (preferred) embodiments thereof, coupled to a robot;
moving said wafer along a path with said robot;
illuminating an outer circumference of said wafer with UV light, encompassing radiation having a wavelength from at least 10 nm to at most 400 nm, emitted from said plurality of light sources and detecting the UV light from said plurality of light sources and/or secondary emissions from said wafer with said plurality of detectors positioned on an opposite side of said wafer, thereby producing an electrical signal;
converting the electrical signal to a digital output signal in said processor, thereby determining the center of said wafer;
determining a difference in position of said wafer relative to an ideal center point of said wafer by using said device;
compensating for any difference in position during subsequent robot movement of said wafer.

In particular embodiments, compensating for any difference in position is conducted during movement of said wafer from a source location to a destination location.

In particular embodiments, said semiconductor processing system is a single wafer or batch processing system.

In particular embodiments, said semiconductor processing system comprises a vertical furnace configured for processing wafers.

### DESCRIPTION OF THE FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 schematically illustrates an exemplary embodiment of a device (100) configured for finding the center of a wafer in a semiconductor processing system according to the disclosure.

FIG. 2 schematically illustrates another exemplary embodiment of a device (200) configured for finding the center of a wafer in a semiconductor processing system according to the disclosure.

FIG. 3 schematically illustrates another exemplary embodiment of a device (300) configured for finding the center of a wafer in a semiconductor processing system according to the disclosure.

FIG. 4 schematically illustrates an exemplary embodiment (400) wherein the present device is connected or connectable to a robot configured for moving a wafer in a semiconductor processing system according to the disclosure.

FIG. 5 schematically illustrates an exemplary embodiment of a method (500) for finding the center of a wafer in a semiconductor processing system according to the disclosure.

FIG. 6 schematically illustrates an exemplary embodiment of a method (600) of accurately positioning a wafer in a semiconductor processing system according to the disclosure.

### DETAILED DESCRIPTION OF EXEMPLARY EMBODIMENTS

Although certain embodiments and examples are disclosed below, it will be understood by those in the art that the present disclosure extends beyond the specifically disclosed embodiments and/or uses of the present disclosure and obvious modifications and equivalents thereof. Thus, it is intended that the scope of the present disclosure should not be limited by the particular disclosed embodiments described below.

In the following detailed description, the technology underlying the present disclosure will be described by means of different aspects thereof. It will be readily understood that the aspects of the present disclosure, as generally described herein, and illustrated in the figures, can be arranged, substituted, combined, and designed in a wide variety of different configurations, all of which are explicitly contemplated and make part of this disclosure. This description is meant to aid the reader in understanding the technological concepts more easily, but it is not meant to limit the scope of the present disclosure, which is limited only by the claims. Hence, the description below is to be regarded as illustrative in nature, and not as restrictive.

As used herein, the singular forms “a”, “an”, and “the” include both singular and plural referents unless the context clearly dictates otherwise. By way of example, “a step” means one step or more than one step.

The terms “comprising”, “comprises” and “comprised of” as used herein are synonymous with “including”, “includes” or “containing”, “contains”, and are inclusive or open-ended and do not exclude additional, non-recited members, elements, or method steps. The terms also encompass “consisting of” and “consisting essentially of”, which enjoy well-established meanings in patent terminology.

Whereas the terms “one or more” or “at least one”, such as one or more members or at least one member of a group of members, is clear per se, by means of further exemplification, the term encompasses inter alia a reference to any one of said members, or to any two or more of said members, such as, e.g., any ≥3, ≥4, ≥5, ≥6 or ≥7 etc. of said members, and up to all said members. In another example, “one or more” or “at least one” may refer to 1, 2, 3, 4, 5, 6, 7 or more.

The terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the disclosure described herein are capable of operation in other sequences than described or illustrated herein.

As used herein, the term “and/or” when used in a list of two or more items, means that any one of the listed items can be employed by itself or any combination of two or more of the listed items can be employed. For example, if a list is described as comprising group A, B, and/or C, the list can comprise A alone, B alone, C alone, A and B in combination, A and C in combination, B and C in combination, or A, B, and C in combination.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” or “in a particular embodiment” in various places throughout this specification are not necessarily all referring to the same embodiment, but may. Furthermore, the particular features, structures or characteristics may be combined in any suitable manner, as would be apparent to a person skilled in the art from this disclosure, in one or more embodiments. Furthermore, while certain embodiments described herein include some but not other features included in other embodiments, combinations of features of different embodiments are meant to be within the scope of the invention, and form different embodiments, as would be understood by those in the art.

The recitation of numerical ranges by endpoints includes all integer numbers and, where appropriate, fractions subsumed within that range (e.g. 1 to 5 can include 1, 2, 3, 4 when referring to, for example, a number of elements, and can also include 1.5, 2, 2.75 and 3.80, when referring to, for example, measurements). The recitation of endpoints also includes the end point values themselves (e.g. from 1.0 to 5.0 includes both 1.0 and 5.0). Any numerical range recited herein is intended to include all sub-ranges subsumed therein. This applies to numerical ranges irrespective of whether they are introduced by the expression “from . . . to . . . ” or the expression “between . . . and . . . ”or another expression.

As used herein, the terms “about” or “approximately” are used to provide flexibility to a numerical value or range endpoint by providing that a given value may be “a little above” or “a little below” said value or endpoint, depending on the specific context. Hence, the terms “about” or “approximately” as used herein when referring to a measurable value such as a parameter, an amount, a temporal duration, and the like, are meant to encompass variations of and from the specified value or endpoint, such as variations of +/−10% or less, preferably +/−5% or less, more preferably +/−1% or less, and still more preferably +/−0.1% or less of and from the specified value, insofar such variations are appropriate to perform in the disclosed invention.

Unless otherwise stated, use of the terms “about” or “approximately” in accordance with a specific number or numerical range should also be understood to provide support for such numerical terms or range without the term “about”. For example, the recitation of “about 30” should be construed as not only providing support for values a little above and a little below 30, but also for the actual numerical value of 30 as well.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

The terms “wt. %,” “vol %”, or “mol %” refers to a weight percentage of a component, a volume percentage of a component, or molar percentage of a component, respectively, based on the total weight, the total volume of material, or total moles, which includes the component.

Reference in this specification may be made to devices, structures, systems, or methods that provide “improved” performance (e.g. increased or decreased results, depending on the context). It is to be understood that unless otherwise stated, such “improvement” is a measure of a benefit obtained based on a comparison to devices, structures, systems or methods in the prior art. Furthermore, it is to be understood that the degree of improved performance may vary between disclosed embodiments and that no equality or consistency in the amount, degree, or realization of improved performance is to be assumed as universally applicable.

As used herein, relative terms, such as “left,” “right,” “front,” “back,” “top,” “bottom,” “over,” “under,” etc., are used for descriptive purposes and not necessarily for describing permanent relative positions. It is to be understood that such terms are interchangeable under appropriate circumstances and that the embodiment as described herein are capable of operation in other orientations than those illustrated or described herein unless the context clearly dictates otherwise.

Objects described herein as being “adjacent” to each other reflect a functional relationship between the described objects, that is, the term indicates the described objects must be adjacent in a way to perform a designated function which may be a direct (i.e. physical) or indirect (i.e. close to or near) contact, as appropriate for the context in which the phrase is used.

Objects described herein as being “connected” or “coupled” reflect a functional relationship between the described objects, that is, the terms indicate the described objects must be connected in a way to perform a designated function which may be a direct or indirect connection in an electrical or nonelectrical (i.e. physical) manner, as appropriate for the context in which the term is used.

In addition, embodiments of the present disclosure may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic based aspects of the present disclosure may be implemented in software (e.g., instructions stored on non-transitory computer-readable medium) executable by one or more processing units, such as a microprocessor and/or application specific integrated circuits. As such, it should be noted that a plurality of hardware and software-based devices, as well as a plurality of different structural components may be utilized to implement the technology of the present disclosure. For example, “servers” and “computing devices” described in the specification can include one or more processing units, one or more computer-readable medium modules, one or more input/output interfaces, and various connections connecting the components.

As used herein, the term “substrate” can refer to any underlying material or materials that can be used to form, or upon which, a device, a circuit, or a film can be formed. The “substrate” may be continuous or non-continuous; rigid or flexible; solid or porous; and combinations thereof. The substrate may comprise a material such as crystalline silicon, silicon carbide, silicon oxide, strained silicon, silicon germanium, sapphire, doped or undoped polysilicon, doped or undoped silicon, patterned or non-patterned silicon on insulator (SOI), carbon doped silicon oxides, silicon nitride, germanium, gallium arsenide, glass, or sapphire.

Implementations described herein will be further described below in reference to a device for finding the center of a wafer and related methods which can be carried out in a semiconductor processing system. However, it should be clear that other systems that benefit from center finding processes may also be adapted to benefit from the implementations described herein. The device described herein is illustrative and should not be construed or interpreted as limiting the scope of the implementations described herein.

An aspect of the present disclosure provides a device for finding the center of a wafer in a semiconductor processing system. The device preferably comprises
a plurality of light sources, each light source being independently operable to emit UV light, encompassing radiation having a wavelength from at least 10 nm to at most 400 nm;
a plurality of detectors, each detector being independently operable to receive said UV-light and produce an electrical signal; and
a processor operatively connected to said plurality of detectors and configured to process said produced electrical signal for determining the center of said wafer.

In other words, in the present description technology is described that relates to the detection and positioning of a wafer during semiconductor manufacturing. The present device can advantageously improve the determination of wafer coordinates, such as the wafer center and/or wafer radius, which may increase throughput and decrease costs of semiconductor production.

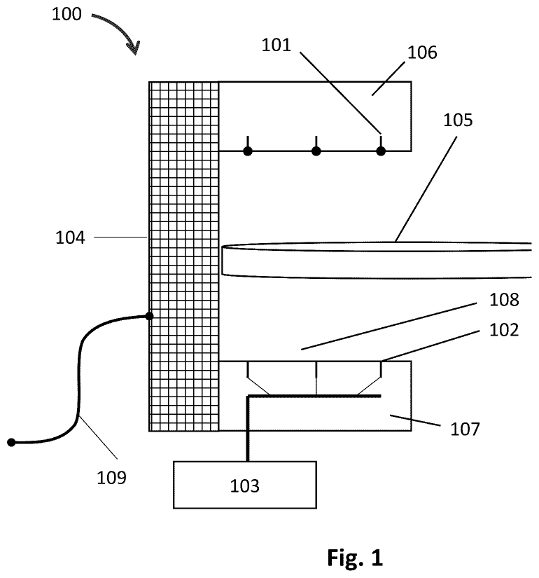

The present device will now be discussed in greater detail with reference to FIG. 1, which shows a top view of a schematic illustration of an exemplary embodiment of a device 100 as described herein. The device 100 can be used to perform the methods as described herein for finding the center of a wafer and/or accurately positioning a wafer in a semiconductor processing system.

In the illustrated example, the device 100 includes three light sources 101, three detectors 102, a processor 103 operatively connected to said detectors 102, and a support 104. In the device 100, a substantially circular wafer 105 may be handled by a robot (not shown) while the coordinates of the wafer, such as the wafer center and/or wafer radius, can be detected.

In general, the device 100 may have a U-shape comprising two spaced-apart legs for passage of the wafer 105 when the wafer is being moved along a defined path. The first leg 106 may support the three spaced-apart light sources 101 and the second leg 107 may support the three-spaced apart detectors 102 so that the light sources 101 and detectors 102 are positioned on opposite sides of the wafer 105 during passage through the device. The interior of the device 108 is not limited to a particular shape, but may be substantially circular with a radius sufficient to accommodate the wafer 105.

The term “wafer” as used herein generally refers to all substrates and other materials that might be handled by a semiconductor processing system. It will be understood that, while the following description is applicable to wafers, and refers specifically to wafers in a number of illustrative embodiments, a variety of other objects may be handled within a semiconductor facility including production wafers, test wafers, cleaning wafers, calibration wafers, or the like, as well as other substrates (such as for reticles, magnetic heads, flat panels, and the like), including substrates having various shapes and sizes such as circular, square, or rectangular substrates. All such workpieces are intended to fall within the scope of the term “wafer” as used herein unless a different meaning is explicitly provided or otherwise clear from the context of the present disclosure. For instance, wafers as described herein may be thin, flat objects with a substantially circular shape. Typical sizes for current wafers include about 100 mm, about 150 mm, about 200 mm, about 300 mm, or larger than 300 mm. Thus it will be understood that the shape and size of the components of the present device may vary, and one skilled in the art would understand how to adapt such components such as the shape and size of the legs 106 and 107, and the support 104 to particular wafer dimensions.

While not specifically limited to a particular composition, wafers as described herein may comprise one or more materials selected from the group consisting of silicon carbide, silicon, silicon germanium, silicon oxide, gallium arsenide, gallium nitride, sapphire, and combinations thereof. Preferably, the presently described wafers comprise silicon carbide as a bulk semiconductor material.

In particular embodiments, wafers as described herein may be at least partially transparent. The present device has the advantage of providing efficient detection of wafers whether transparent materials are used or not.

The term “light source” as used herein refers to any object or component that is configured to emit electromagnetic radiation in the UV wavelength range (i.e., around 10-400 nm). This emission may be continuous, pulsed, or modulated and can originate from various technologies, including but not limited to, light-emitting diodes (LEDs), lasers, lamps, or other photonic devices.

In some embodiments, each light source may be independently operable to emit UV-A light, encompassing radiation having a wavelength from at least 315 nm to at most 400 nm.

In some embodiments, each light source may be independently operable to emit UV-B light, encompassing radiation having a wavelength from at least 280 nm to at most 315 nm.

In some embodiments, each light source may be independently operable to emit UV-C light, encompassing radiation having a wavelength from at least 100 nm to at most 280 nm.

In some embodiments, each light source may be independently operable to emit NUV light, encompassing radiation having a wavelength from at least 300 nm to at most 400 nm.

In some embodiments, each light source may be independently operable to emit MUV light, encompassing radiation having a wavelength from at least 200 nm to at most 300 nm.

In some embodiments, each light source may be independently operable to emit FUV light, encompassing radiation having a wavelength from at least 122 nm to at most 200 nm.

In some embodiments, each light source may be independently operable to emit EUV light, encompassing radiation having a wavelength from at least 10 nm to at most 121 nm.

In preferred embodiments, the present light sources 101 are LEDs configured to emit UV light, and preferably UV-A light, when an electrical current passes through it. Advantageously, LEDs can be configured such that each individual element can be switched on and off rapidly to permit multiple measurements to be taken using different angles at any given wafer position. The present plurality of light sources can be comprised of DIP (Dual In-Line Package) LEDs, SMD (Surface mounted diode) LEDs, COB (Chip on Board) LEDs, or combinations thereof. However, the present disclosure is not limited to said designs and, in alternative embodiments, the LEDs may be soldered or attached as separate components (e.g., through-hole diodes) to a printed circuit board (PCB).

The plurality of light sources 101 used in the present device 100 may illuminate, project, or transmit light such that a light path is formed between the light sources 101 and the detectors 102.

The light beams emitted by the present light sources 101 may be directed to the outer circumference of the wafer 105 when passing the wafer 105 through the present device 100. Said light beams typically strike the wafer's edge, and the light is either transmitted, reflected, or blocked by the wafer's edge, depending on the setup.

The plurality of UV emitting light sources of the present disclosure can be provided in various shapes, sizes, and configurations depending on the application requirements. For instance, the light sources may have a circular geometry, featuring a central light-emitting region surrounded by a circular or elliptical lens. This design is particularly advantageous for focused irradiation. In another embodiment, the light sources may have a rectangular or square shape. This has the advantage that the plurality of light sources may be easily integrated onto printed circuit boards (PCBs).

The present plurality of light sources 101 may be arranged in an array. For instance, UV emitting LED chips may be used that can be configured to operate in series or in parallel.

The term “detector” as used herein refers to any object or component that is configured to sense, measure, and/or analyze UV light, and preferably UV-A light, emitted by the plurality of light sources, for instance after it interacts with a target or medium (e.g., a wafer as defined herein).

In some embodiments, each light source is paired with at least one corresponding detector that is configured to detect the exact position where the UV light intersects or is interrupted by the wafer's outer edge.

In accordance with the present disclosure, the plurality of detectors convert the incoming light into an electrical signal or other measurable output, which can then be processed in a suitable processor to extract relevant information. Non-limiting examples of suitable detectors include photodiodes, photomultiplier tubes, and charge-coupled devices (CCDs).

Preferably, the present detectors are photodiodes designed to detect UV light. It has been found herein that photodiodes may advantageously provide for better signal transmission/detection speed.

An advantage of the present device is that the plurality of detectors may be specifically designed to match the wavelength, and preferably intensity, of the light emitted by the plurality of light sources, thereby ensuring accurate and efficient detection of wafers.

In preferred embodiments, and as schematically illustrated in FIG. 1, at least three light sources are paired with at least three detectors, such as three light sources paired with three detectors, or five light sources paired with five detectors, or seven light sources paired with seven detectors. This creates three, five, or seven distinct detection points, respectively. Since the positions of the light sources and detectors are known and fixed, these points can be used to mathematically determine the wafer's coordinates using trigonometric relations. The suitable number and placement of light sources and detectors may vary depending on the size of the wafer.

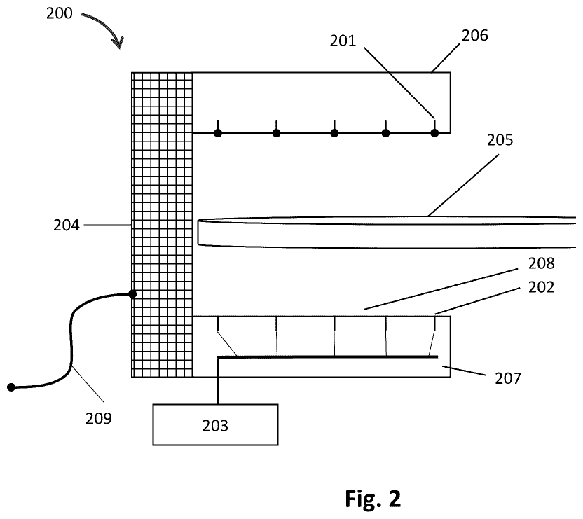

FIG. 2 schematically illustrates another exemplary embodiment of a device 200 as described herein. The device 200 can be used to perform the methods as described herein for finding the center of a wafer and/or accurately positioning a wafer in a semiconductor processing system.

In the illustrated example, the device 200 includes five light sources 201, five detectors 202, a processor 203 operatively connected to said detectors 202, and a support 204. In the device 200, a substantially circular wafer 205 may be handled by a robot (not shown) while the coordinates of the wafer, such as the wafer center and/or wafer radius, can be detected.

In general, the device 200 may have a U-shape comprising two spaced-apart legs for passage of the wafer 205 when the wafer is being moved along a defined path. The first leg 206 may support the five spaced-apart light sources 201 and the second leg 207 may support the three-spaced apart detectors 202 so that the light sources 201 and detectors 202 are positioned on opposite sides of the wafer 205 during passage through the device. The interior of the device 208 is not limited to a particular shape, but may be substantially circular with a radius sufficient to accommodate the wafer 205.

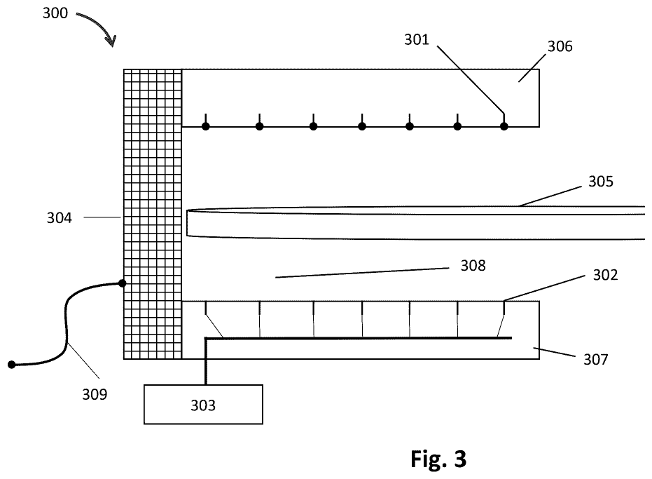

FIG. 3 schematically illustrates another exemplary embodiment of a device 300 as described herein. The device 300 can be used to perform the methods as described herein for finding the center of a wafer and/or accurately positioning a wafer in a semiconductor processing system.

In the illustrated example, the device 300 includes seven light sources 301, seven detectors 302, a processor 303 operatively connected to said detectors 302, and a support 304. In the device 300, a substantially circular wafer 305 may be handled by a robot (not shown) while the coordinates of the wafer, such as the wafer center and/or wafer radius, can be detected.

In general, the device 300 may have a U-shape comprising two spaced-apart legs for passage of the wafer 305 when the wafer is being moved along a defined path. The first leg 306 may support the five spaced-apart light sources 301 and the second leg 307 may support the three-spaced apart detectors 302 so that the light sources 302-1 and detectors 302 are positioned on opposite sides of the wafer 305 during passage through the device. The interior of the device 308 is not limited to a particular shape, but may be substantially circular with a radius sufficient to accommodate the wafer 305.

In an embodiment, the electrical output signal of the plurality of detectors may have a first value when the beam of UV light is incident on the surface of the plurality of detectors and has a second value when the beam is not incident on the plurality of detectors. When passing a wafer through the present device during operation, the output of the plurality of detectors can change from the first value to the second value and vice versa.

In particular embodiments, and as illustrated in FIG. 1, the plurality of detectors 102 may be positioned opposite to the plurality of light sources 101 such that a light path from the plurality of light sources 101 to the plurality of detectors 102 comprises a predetermined position within the device 100. For instance, the light sources and detectors may be aligned directly with each other. Alternatively, the light sources and detectors may be positioned at different angles while relying on scattering, fluorescence, or diffusion for light detection. It should be clear that the skilled person would understand how to arrange the light sources and detectors for optimal detection accuracy.

The present detector's design, including its shape, size, and configuration, may be varied depending on the application. For instance, the detectors may have a circular active area, alternatively the detectors may have a square or rectangular shape.

An advantage of the present detectors is that they do not necessarily require an optical filter to block unwanted wavelengths from reaching the active area of each detector.

In preferred embodiments, each light source 101 is independently operable to emit UV-A light, encompassing radiation having a wavelength from at least 315 nm to at most 400 nm, and each detector 102 is independently operable to receive said UV-A light and produce an electrical signal.

Preferably, each light source is independently operable to emit UV-A light at a peak wavelength of around 365 nm; and preferably each detector is independently operable to receive UV-A light at a peak wavelength of around 365 nm.

It should be clear that the peak wavelength of the light sources 101 refers to the specific wavelength at which the material emits the maximum intensity of light, while the peak wavelength of the detectors 102 refers to the specific wavelength at which the material is most sensitive or responds with the highest efficiency. It has been found herein that when the peak wavelength of the plurality of light sources and the plurality of detectors closely match, may result in improved data transmission and wafer detection.

The distance between the light sources 101 and detectors 102, optionally each independently arranged in an array, will generally be determined by the size of wafers or other substrates handled by the device. In an embodiment, the positions of the light sources and detectors may be adjustable to increase or decrease the distance between each component while maintaining the linear and diagonal relationships discussed above. In this manner, the device 100 may advantageously be readily adapted to wafers of different sizes.

In particular embodiments, the longitudinal distance between the plurality of light sources and the plurality of detectors is from at least 10 mm to at most 300 mm, or from at least 10 mm to at most 290 mm, or from at least 10 mm to at most 280 mm, or from at least 10 mm to at most 270 mm, or from at least 10 mm to at most 260 mm, or from at least 10 mm to at most 250 mm, or from at least 10 mm to at most 200 mm, or from at least 10 mm to at most 150 mm, or from at least 10 mm to at most 100 mm, or from at least 15 mm to at most 100 mm.

In particular embodiments, the present device further comprises a housing enclosing said plurality of light sources and said plurality of detectors; and wherein said housing comprises holes such that light is transmittable between said plurality of light sources and said plurality of detectors.

A suitable housing for enclosing said plurality of light sources and said plurality of detectors is typically designed to protect said components and optimize their performance. The housing may be made of a suitable metal or plastic material and may have a circular or rectangular shape, depending on the application.

In preferred embodiments, said housing comprises holes and said holes may have sizes ranging from 0.1 to 3.0 mm, preferably 0.5 mm to 2 mm. It has been found herein that the hole size may control the intensity of UV light emitted by the plurality of light sources. Therefore, advantageously allowing to improve the quality of the signal measured by the plurality of detectors.

In particular embodiments, the present device may further comprise one or more low-pass filters connected or connectable to the plurality of light sources and/or the plurality of detectors. This may advantageously ensure that only specific light with a desired frequency/wavelength reaches the target, improving the clarity and quality of results.

When used, for example, in conjunction with the plurality of light sources 101, said low-pass filters may help control the frequency (or wavelength) of the emitted light.

Alternatively, when used in conjunction with the plurality of detectors 102, said low-pass filters may help control the frequency (or wavelength) of incident light, thereby improving signal quality and reducing noise.

The term “processor” as used herein refers to a computational device or component configured to receive and analyze the data or signals generated by the plurality of detectors and determine the center of the wafer.

In some embodiments, the present processor may be configured to perform functions such as signal processing, data analysis, and/or control operations.

In some embodiments, the processor may be configured to apply algorithms to interpret the detected signals, extract relevant information, and/or make decisions based on the data.

In some embodiments, the processor may be configured to provide feedback to adjust the operation of the plurality of light sources and plurality of detectors. This has the advantage that the overall system's accuracy and functionality may be enhanced.

In particular embodiments, the processor comprises a field effect transistor, preferably a metal-oxide-semiconductor field-effect transistor. The field effect transistor allows to convert (analog) electrical signals produced by the plurality of detectors into a digital output signal. This advantageously allows for advanced processing, analysis, and decision-making.

The digital signal output produced by the processor may be manipulated, stored, or analyzed using software algorithms. Hence, allowing for pattern recognition, data logging, and real-time monitoring of the wafer when passing through the device.

In particular embodiments, the present device further comprises a signal amplifier arranged between the plurality of detectors 102 and processor 103; and wherein said signal amplifier is configured to amplify the electrical signal produced by said plurality of detectors 102.

Non-limiting examples of suitable signal amplifiers include transimpedance amplifiers (TIAs) and operational amplifiers (Op-Amps).

To further improve signal processing, the present device may also comprise a comparator arranged between the signal amplifier and the processor 103. The comparator, working alongside the signal amplifier, may convert the analog signal (output from the amplifier) into a digital signal or triggers certain actions based on the signal strength. For instance, the comparator may generate a clean digital pulse signal.

In particular embodiments, the plurality of detectors are photodiodes and the present device further comprises a signal amplifier arranged between said photodiodes and processor; and said signal amplifier is configured to convert an electrical current produced by said photodiodes to a voltage signal.

In particular embodiments, the plurality of detectors are photodiodes and the present device further comprises a signal amplifier and comparator arranged between said photodiodes and processor; and said signal amplifier is configured to convert an electrical current produced by said photodiodes to a voltage signal which may subsequently be converted in the comparator to generate a digital signal.

In an exemplary embodiment, the plurality of detectors are photodiodes and the signal amplifier is a transimpedance amplifier and said transimpedance amplifier is configured to convert an electrical current produced by said photodiodes to a voltage signal.

In particular embodiments, the present device further comprises a grounded conductive plate (109, 209, 309) configured for removing static charge buildup in the wafer during operation of said device. This has the advantage that during movement of the wafer, the wafer can be discharged to avoid static discharge during further processing steps in the semiconductor processing system. The grounded conductive plate is preferably connected to the support 104.

In particular embodiments, the present device is connected or connectable to a robot configured for moving a wafer in a semiconductor processing system. The robot may be configured to move the wafer along a predetermined path within the semiconductor processing system. For instance, the robot may be designed to ensure accurate positioning and safe handling of wafers throughout various stages of the manufacturing process, including wafer transfer between process chambers, storage cassettes, and inspection stations.

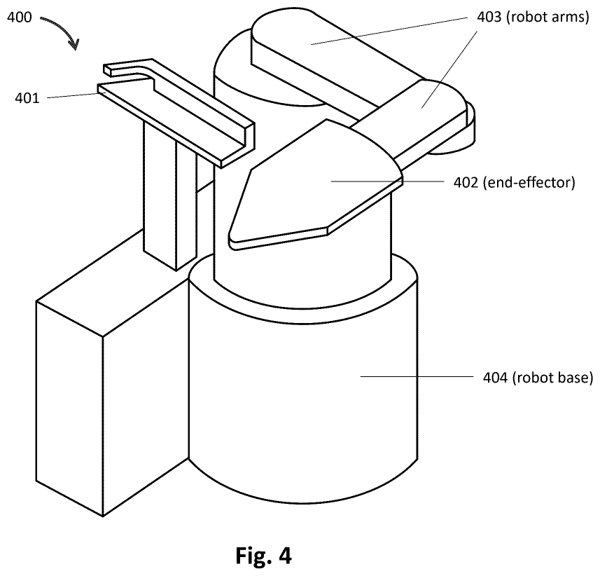

FIG. 4 schematically illustrates an exemplary embodiment 400 wherein the present device 401 is connected or connectable to a robot configured for moving a wafer in a semiconductor processing system. In said exemplary configuration, the robot comprises a multi-axis articulated arm system, equipped with a wafer end-effector specifically designed for gripping, lifting, and maneuvering wafers. The arm system is driven by a combination of rotary and linear actuators, enabling precise control over the robot's movement in multiple degrees of freedom. The robot's architecture typically includes a base 404, an arm assembly 403, and the end-effector 402, each optimized to handle wafers of varying diameters.

The end-effector 402 is configured with a compliant gripping mechanism that employs, for example, one or more of vacuum suction, electrostatic force, or edge-contact grippers, depending on the specific application and wafer material. The gripping mechanism is designed to securely hold the wafer while minimizing the risk of mechanical stress, particle generation, or slippage during transfer.

In preferred embodiments, the present device may be operable as an integrated alignment system that accurately determines the position and orientation of the wafer during handling.

In preferred embodiments, the present device may be coupled to a robot and said device and said robot may be operatively connected to a system controller configured to control the plurality of light sources, plurality of detectors, the processor, and the movement of the wafer during operation. The system controller may include a central processing unit (CPU), memory, and support circuits (or I/O). Software instructions and data can be coded and stored within the memory for instructing the CPU. A program (or computer instructions) readable by the system controller determines which tasks are performable on the wafer. In some implementations, the program is software readable by the system controller, which includes code to generate and store at least wafer positional information, the sequence of movements of the various controlled components, and any combination thereof. The system controller may be coupled to the respective components of the device and robot through suitable cabling.

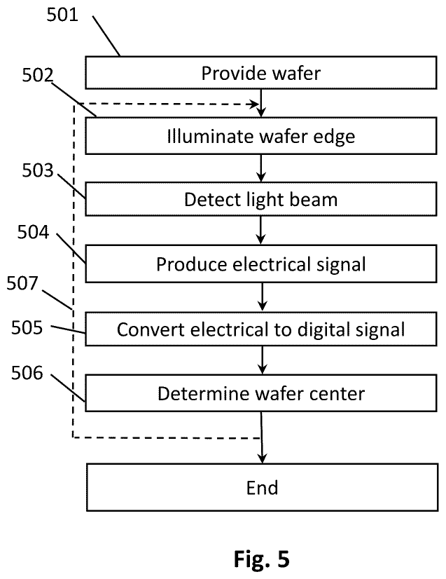

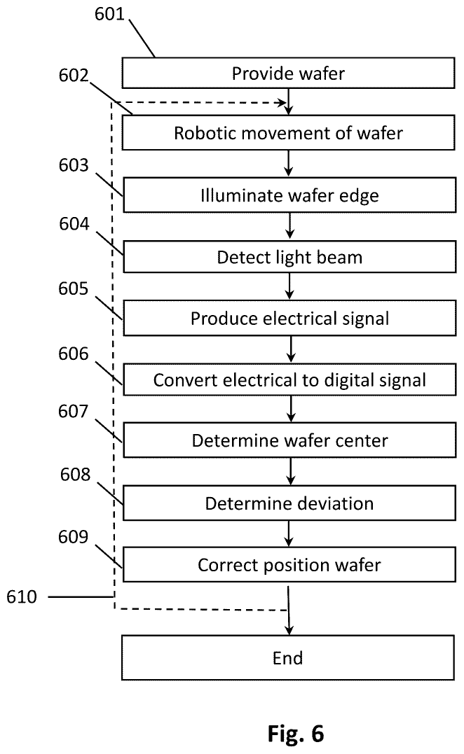

The system controller may include a processor, logic circuitry, and/or any combination of hardware and software that is adapted to use the present device and execute the methods of the present disclosure. For example, the system controller can include program code that is operable to activate the plurality of light sources to illuminate the wafer in response to receiving a signal indicating the center-finding should begin (e.g., a wafer is expected to be present). The system controller can include program code that is operable to use the plurality of light sources and the plurality of detectors to locate the edges and center of a wafer in the device in accordance with the methods detailed below and exemplified in FIGS. 5-6. The system controller can include program code that is adapted to calibrate the device to control the intensity of the light sources, and/or to adjust the gain of the detectors. The system controller can also include interface ports, memory, clocks, power supplies, and other components to support operation of the system controller.

Although the paragraphs described above refer to a single system controller, it should be appreciated that multiple system controllers may be used with the implementations as described herein.

For instance, in one implementation, a first controller controls robotic movement of the wafer and a second controller controls automation of the wafer finding procedure provided in the present disclosure. The first controller arranged to use data from the second controller allows information about the position of the wafer calculated by the second controller to be used immediately to adjust the movement of the robot configured for handling the wafer. When, for example, measurements indicate that the wafer is systematically displaced over a certain distance, the first controller may instruct the robot to deliver the wafer to a corrected delivery position, thus counterbalancing systematic displacement.

Another aspect of the present disclosure provides a method for finding the center of a wafer in a semiconductor processing system. The method preferably comprising the steps of
providing a wafer to a device, comprising a plurality of light sources, a plurality of detectors, and a processor operatively connected to said plurality of detectors;
illuminating the outer circumference of said wafer with UV light, encompassing radiation having a wavelength from at least 10 nm to at most 400 nm, emitted by said plurality of light sources and detecting the UV light from said plurality of light sources and/or secondary emissions from said wafer with said plurality of detectors, thereby producing an electrical signal;
converting the electrical signal to a digital output signal in the processor, thereby determining the center of the wafer.

It should be clear that (preferred) embodiments and associated advantages of the device according to an aspect of the present disclosure are also (preferred) embodiments of the method for finding the center of a wafer in a semiconductor processing system according to an aspect of the present disclosure and vice versa.

FIG. 5 illustrates a flow diagram of an exemplary embodiment of a method 400 for finding the center of a wafer in a semiconductor processing system according to an aspect of the present disclosure. The method starts (501) after a wafer has been provided to a device comprising a plurality of light sources, a plurality of detectors, and a processor operatively connected to said plurality of detectors as described herein. The wafer finding procedure comprises emitting UV light from the plurality of light sources (502) such that the outer circumference or edge of the wafer is illuminated when passing the wafer through the device. By passing the wafer through the device, the series of light beams emitted by the plurality of light sources will be interrupted and reflect of the wafer's edge, which is detected by the plurality of detectors (503), preferably positioned opposite to the plurality of light sources. The detected UV light emitted from the plurality of light sources and/or secondary emissions from the wafer subsequently produces an electrical signal (504). The electrical signal produced by the plurality of detectors is then sent to the processor operatively connected to said plurality of detectors. This signal is subsequently converted in the processor to a digital output signal (505), thereby determining the position of the wafer and allowing to accurately measure the wafer's edge profile.

The wafer's edge profile can then be used to geometrically calculate the center position of the wafer by the processor. Typically, this involves fitting a circle to the detected edge points and finding the circle's center, which corresponds to the center of the wafer. The calculation preferably takes into account all the detected edge points to ensure that the center is accurately determined, even if the wafer has an irregular shape or minor defects along the edge.

The following description illustrates how in embodiments of the present disclosure the center point of a(n) (off-centered) wafer may be calculated. First, the device is calibrated by determining the center of a calibration wafer, the location of the plurality of light sources, and optionally, the location of the wafer boat designed to securely hold and support wafers during various stages of wafer processing. The center of each respective wafer can then be determined by its offset from the center of the calibrated wafer. More specifically, the coordinates of the wafer center of each subsequent wafer can be determined by measuring the distance between each light source of the plurality of light sources and the leading edge (i.e., first portion of wafer to enter processing tool, machine, or system) and trailing edge (i.e., last portion of wafer to enter processing tool, machine, or system of the wafer) of the wafer. Based on these measurements and the radius of the respective wafer, the coordinates of the wafer center are calculated through standard trigonometric relations.

If the wafer is not perfectly centered in the present device, the processor can still calculate the true center based on the edge profile. This allows for correction of the wafer's position, ensuring that subsequent processes (like lithography or etching) are precisely aligned with the actual center of the wafer.

In some embodiments, the processor can acquire and store data (e.g., coordinates of the wafer position, such as the wafer center) for later processing, or analyze the data in real-time.

As depicted in FIG. 5, the method 500 may be repeated indefinitely (507) as the wafer is moved through various locations of the semiconductor processing system. It is understood that additional steps can be provided before, during, and after the steps of the method described herein above, and that some of the steps described can be replaced or eliminated for other implementations of the method. For example, although not shown, the method 500 may also detect any misalignment, tilts, or eccentricities and adjust the handling or processing equipment in the semiconductor processing system accordingly.

The method 500 may be executed as a software routine by a system controller (as described herein) operatively connected to the present device.

Another aspect of the present disclosure provides a method for accurately positioning a wafer in a semiconductor processing system. The method preferably comprising the steps of
providing a wafer to a device, comprising a plurality of light sources, a plurality of detectors, and a processor operatively connected to said plurality of detectors, coupled to a robot;
moving the wafer along a path with the robot;
illuminating an outer circumference of said wafer with UV light, encompassing radiation having a wavelength from at least 10 nm to at most 400 nm, emitted from said plurality of light sources and detecting the UV light from said plurality of light sources and/or secondary emissions from said wafer with said plurality of detectors positioned on an opposite side of said wafer, thereby producing an electrical signal;
converting the electrical signal to a digital output signal in the processor, thereby determining the center of the wafer;
determining a difference in center of the wafer relative to an ideal center point of the wafer by using the device;
compensating for any difference in position during subsequent robot movement of the wafer.

It should be clear that (preferred) embodiments and associated advantages of the device according to an aspect of the present disclosure and the method for finding the center of a wafer in a semiconductor processing system according to an aspect of the present disclosure are also (preferred) embodiments of the method for accurately positioning a wafer in a semiconductor processing system according to an aspect of the present disclosure and vice versa.

FIG. 6 illustrates a flow diagram of an exemplary embodiment of a method 600 for accurately positioning a wafer in a semiconductor processing system according to an aspect of the present disclosure. The method starts (601) after a wafer has been provided to a device comprising a plurality of light sources, a plurality of detectors, and a processor operatively connected to said plurality of detectors as described herein. The device is coupled to a robot configured for moving the wafer to various locations of the semiconductor processing system. Next, the wafer is moved along a path with the robot (602) and the wafer is passed through the device coupled to the robot to determine the center of the wafer during robotic movement.

The wafer finding procedure comprises emitting UV light from the plurality of light sources (603) such that the outer circumference or edge of the wafer is illuminated when passing the wafer through the device. By passing the wafer through the device, the series of light beams emitted by the plurality of light sources will be interrupted and reflect of the wafer's edge, which is detected by the plurality of detectors (604), preferably positioned opposite to the plurality of light sources. The detected UV light emitted from the plurality of light sources and/or secondary emissions from the wafer subsequently produces an electrical signal (605). The electrical signal produced by the plurality of detectors is then sent to the processor operatively connected to said plurality of detectors. This signal is subsequently converted in the processor to a digital output signal (606), thereby determining the position of the wafer and allowing to accurately measure the wafer's edge profile. Mathematical calculations (as described above) subsequently allow to determine the center of the wafer (607).

In the event that the wafer is not perfectly centered in the present device during or after robotic movement, the difference in position of the wafer relative to an ideal center point of the wafer is determined (608). The robot coupled to the present device subsequently compensates for any difference or deviation in the wafer's position (609), ensuring that subsequent processes (like lithography or etching) are precisely aligned with the actual center of the wafer.

As depicted in FIG. 6, the method 600 may be repeated indefinitely (610) as the wafer is moved through various locations of the semiconductor processing system. It is understood that additional steps can be provided before, during, and after the steps of the method described herein above, and that some of the steps described can be replaced or eliminated for other implementations of the method. For example, although not shown, the method 600 may also detect any misalignment, tilts, or eccentricities and adjust the handling or processing equipment in the semiconductor processing system accordingly.

Details of various robotic movement and handling operations of the wafer are well known in the art, and any such movement or handling functions may be suitable employed with the process as described herein and depicted in FIG. 6. This includes various combinations of extensions, retractions, and rotations of the robot, z-axis motion and any other operations that might be usefully employed in wafer handling during semiconductor manufacturing.

In particular embodiments, determining a difference in position of the wafer relative to an ideal center point of the wafer may comprise comparing a determined center of the wafer to an ideal center point of the wafer. More specifically, and advantageously, the present method provides that deviations of the wafer's center from the true wafer center may be corrected during various robotic movements.

In particular embodiments, compensating for any difference in position may be conducted during movement of the wafer from a source location to a destination location. The source location and destination location may be any locations within a semiconductor processing system including other robots or robotic handlers, buffer or transition stations, process modules of any kind, and/or other modules for supplemental processes such as cleaning, scanning, and other processes.

In particular embodiments, compensating for any difference in position is conducted by placing the wafer on a staging position and picking-up the wafer at a corrected position.

In particular embodiments, moving the wafer along a path with the robot comprises loading the wafer into a wafer boat to subsequently be inserted into a processing chamber of a semiconductor processing system. The “wafer boat” as described herein is a carrier specifically designed to securely hold and support wafers during various stages of wafer processing, including thermal treatments such as oxidation, diffusion, and annealing, as well as during transport and storage. The boat is configured to maintain the wafers in a fixed orientation and spacing, ensuring uniform processing and minimizing the risk of damage or contamination.

In particular embodiments, the semiconductor processing system is a single wafer or batch processing system.

The method 600 may be executed as a software routine by a system controller as described herein operatively connected to the present device and robot.

The present disclosure further encompasses a semiconductor processing system, the system comprising
a processing chamber comprising one or more openings for receiving wafers;
a device, comprising a plurality of light sources, each light source being independently operable to emit UV light, encompassing radiation having a wavelength from at least 10 nm to at most 400 nm; a plurality of detectors, each detector being independently operable to receive said UV light and produce an electrical signal; and a processor operatively connected to said plurality of detectors and configured to process the produced electrical signal for determining the center of said wafer; and
a robot operatively connected to the device for accurately positioning wafers into the processing chamber.

In particular embodiments, the processing chamber is a vertical furnace. The “vertical furnace”
as described herein may, in embodiments, be a furnace for carrying out processes such as, for example, oxidation, film deposition or diffusion. The furnace operates in a vertical configuration, which optimizes space utilization, enhances uniformity in thermal processing, and allows for the precise control of environmental conditions within the processing chamber.

In particular embodiments, the system further comprises a wafer boat configured for introducing wafers into the processing chamber; and wherein the robot is configured for loading wafers into the wafer boat. Typically, the wafer boat is designed such that the wafers are arrangeable in a parallel, spaced-apart configuration.

During operation of the present system, wafers may be loaded and unloaded from the wafer boat by using the robot operatively connected to the present device. During said robotic movements of the wafer, the device is used to determine the wafer's position and correct for any deviations of the wafer's center by using the methods as presently disclosed. After loading of the wafer boat, it may subsequently be placed on a suitable vertically movable platform or lift, which raises the wafer boat into the process chamber.

In some implementations, the system is designed to electrically interface to, or readily be adapted to interface to, all wafer-processing systems. This interface is designed to be simple in nature to enhance flexibility. The system can include an interactive and configurable system interface and use, for example, serial data transfer for communication with and/or control by a host system or controller. However, the presence and use of such interfaces is optional and not required for operation.

1. Device configured for finding the center of a wafer in a semiconductor processing system, said device comprising
a plurality of light sources, each light source being independently operable to emit UV light, encompassing radiation having a wavelength from at least 10 nm to at most 400 nm;
a plurality of detectors, each detector being independently operable to receive said UV-light and produce an electrical signal; and
a processor operatively connected to said plurality of detectors and configured to process said produced electrical signal for determining the center of said wafer.

2. The device according to claim 1, wherein each light source is independently operable to emit UV-A light, encompassing radiation having a wavelength from at least 315 nm to at most 400 nm, and wherein each detector is independently operable to receive said UV-A light and produce an electrical signal.

3. The device according to claim 1, wherein each light source is independently operable to emit UV-A light at a peak wavelength of around 365 nm; and preferably wherein each detector is independently operable to receive UV-A light at a peak wavelength of around 365 nm.

4. The device according to claim 1, wherein said plurality of light sources are light-emitting diodes.

5. The device according to claim 1, wherein said plurality of detectors are photodiodes.

6. The device according to claim 1, wherein said device further comprises a signal amplifier arranged between the plurality of detectors and processor; and wherein said signal amplifier is configured to amplify the electrical signal produced by said plurality of detectors.

7. The device according to claim 1, wherein said wafer comprises one or more material selected from the group consisting of silicon carbide, silicon, silicon germanium, silicon oxide, gallium arsenide, gallium nitride, sapphire, and combinations thereof; and preferably wherein said wafer comprises silicon carbide as a bulk semiconductor material.

8. The device according to claim 1, wherein said plurality of detectors are positioned opposite to said plurality of light sources such that a light path from said plurality of light sources to said plurality of detectors comprises a predetermined position within said device.

9. The device according to claim 8, wherein a longitudinal distance between said plurality of light sources and said plurality of detectors is from at least 10 mm to at most 300 mm.

10. The device according to claim 1, wherein said device further comprises a housing enclosing said plurality of light sources and said plurality of detectors; and wherein said housing comprises holes such that light is transmittable between said plurality of light sources and said plurality of detectors.

11. The device according to claim 10, wherein said holes have a size ranging from 0.1 to 3.0 mm.

12. The device according to claim 1, wherein said device further comprises a grounded conductive plate configured for removing static charge buildup during operation of said device.

13. The device according to claim 1, wherein said device is connected or connectable to a robot configured for moving said wafer in a semiconductor processing system.

14. Method for finding the center of a wafer in a semiconductor processing system, the method comprising the steps of
providing a wafer to a device, comprising a plurality of light sources, a plurality of detectors, and a processor operatively connected to said plurality of detectors; and
illuminating the outer circumference of said wafer with UV light, encompassing radiation having a wavelength from at least 10 nm to at most 400 nm, emitted by said plurality of light sources and detecting the UV light from said plurality of light sources and/or secondary emissions from said wafer with said plurality of detectors, thereby producing an electrical signal;
converting the electrical signal in said processor, thereby determining the center of said wafer.

15. The method according to claim 14, wherein each light source is independently operable to emit UV-A light, encompassing radiation having a wavelength from at least 315 nm to at most 400 nm, and wherein each detector is independently operable to receive said UV-A light and produce an electrical signal.

16. The method according to claim 14, wherein said plurality of light sources are light-emitting diodes.

17. The method according to claim 14, wherein said plurality of detectors are photodiodes.

18. Method for accurately positioning a wafer in a semiconductor processing system, the method comprising the steps of
providing a wafer to a device, comprising a plurality of light sources, a plurality of detectors, and a processor operatively connected to said plurality of detectors, coupled to a robot;
moving said wafer along a path with said robot;
illuminating an outer circumference of said wafer with UV light, encompassing radiation having a wavelength from at least 10 nm to at most 400 nm, emitted from said plurality of light sources and detecting the UV light from said plurality of light sources and/or secondary emissions from said wafer with said plurality of detectors positioned on an opposite side of said wafer, thereby producing an electrical signal;
converting the electrical signal to said processor, thereby determining the center of said wafer;
determining a difference in center of said wafer relative to an ideal center point of said wafer by using said device; and
compensating for any difference in position during subsequent robot movement of said wafer.

19. The method according to claim 18, wherein compensating for any difference in position is conducted during movement of said wafer from a source location to a destination location.

20. The method according to claim 18, wherein said semiconductor processing system is a single wafer or batch processing system; and preferably wherein said semiconductor processing system comprises a vertical furnace configured for processing wafers.
